(19) United States
(12) Patent Application Publication
(10) Pub. No.: US 2024/0069134 A1
(43) Pub. Date: Feb. 29, 2024

(54) SYSTEM AND METHOD FOR B1-SELECTIVE EXCITATION FOR SPATIAL LOCALIZATION IN MAGNETIC RESONANCE IMAGING

(71) Applicants: Case Western Reserve University, Cleveland, OH (US); Vanderbilt University, Nashville, TN (US)

(72) Inventors: Jonathan B. Martin, Nashville, TN (US); William A. Grissom, Nashville, TN (US); Mark A. Griswold, Cleveland, OH (US)

(21) Appl. No.: 18/547,549

(22) PCT Filed: Feb. 24, 2022
(86) PCT No.: PCT/US22/17717

§ 371 Date: Aug. 23, 2023

Related U.S. Application Data
(60) Provisional application No. 63/153,236, filed on Feb. 24, 2021.

(51) Int. Cl. G01R 33/483; G01R 33/54

(52) U.S. Cl. CPC G01R 33/4831; G01R 33/543

(57) ABSTRACT

A system and method is provided using a nuclear magnetic resonance (NMR) system. The method includes applying an off-resonance radio frequency (RF) pulse using a radio-frequency coil that is spatially inhomogeneous to induce a B1-dependent resonant frequency shift in spins in a subject and, in the presence of the off-resonance RF pulse, applying a frequency-modulated, frequency-selective RF excitation pulse to spatially encode the spins in the subject. The method also includes acquiring NMR data from the subject that is spatially encoded and reconstructing the NMR data to produce a report of internal materials forming the subject.

### CROSS-REFERENCE TO RELATED APPLICATIONS

This application is supported by, based on, and incorporates herein by reference in its entirety, U.S. Provisional Application Ser. No. 63/153,236, filed Feb. 24, 2021.

### STATEMENT REGARDING FEDERALLY SPONSORED RESEARCH OR DEVELOPMENT

This invention was made with government support under Grant No. 1R01EB030414-01 awarded by the National Institutes of Health. The government has certain rights in the invention.

### BACKGROUND

The present disclosure relates generally to systems and methods for nuclear magnetic resonance (NMR) techniques and processes and, more particularly, systems and methods for magnetic resonance imaging (MRI) using pulse sequences that use selective radio frequency (RF) excitation for spatial localization.

When human tissue or other substance is subjected to a uniform magnetic field (polarizing field B₀), the individual magnetic moments of the nuclei in the tissue attempt to align with the polarizing field, and precess about it in random order at their characteristic Larmor frequency. If the tissue, or substance, is subjected to a magnetic field (excitation field B₁) that is in the x-y plane and near the Larmor frequency, the net aligned moment, M_{z}, may be rotated, or “tipped”, into the x-y plane to produce a net transverse magnetic moment M_{xy}. An NMR or magnetic resonance (MR) signal is emitted by the excited nuclei or “spins”, after the excitation signal B₁ is terminated, and the signal may be received and processed to form an image.

When utilizing MR signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using various reconstruction techniques.

Thus, in conventional MR imaging, one gradient is used for localizing excitation to a slice, and two additional perpendicular gradients spatially encode signals from within the excited slice in order to encode the data for image formation from the received MR signals.

Unfortunately, B₀ gradients have a number of drawbacks, including high cost and patient discomfort due to their loud noise and peripheral nerve stimulation. Also, the B₀ gradients are produced by dedicated gradient coils that produce linear gradients applied over the B₀ field to enable spatial encoding of the MR signals. However, dedicated B₀ gradient systems are costly to manufacture and are bulky.

As such, a few spatial encoding methods have been proposed that use RF coils to produce the gradients relative to the B₀ field to spatially encode the MR signals in a manner that is consistent with that typically performed with gradient coils. These RF-gradients techniques do not suffer from the above drawbacks of dedicated gradient coil systems, such as the noise created by dedicated gradient systems or the peripheral nerve stimulation that some experience. Unfortunately, these techniques for using RF coils to apply gradients require linear RF amplitude, which is challenging to implement, or phase gradient coils, which necessitates specialized hardware. Further still, these systems and methods that attempt to use RF coils to apply spatial encoding gradients to the MR signals often result in insufficient encoding, which degrades image quality.

Therefore, there is a need for new techniques for improved systems and methods for acquiring and processing MR or NMR signals.

### SUMMARY

The present disclosure provides systems and methods that provide a robust alternative for spatial encoding that overcomes these drawbacks. In one non-limiting example, a substantially, off-resonant RF pulse can be used to induce a spatially dependent shift in the resonant frequencies of spins within an object to be imaged. Then the frequency-selective excitation pulse can be applied over the off-resonant RF pulse to generate a spatially-selective excitation and acquire spatially encoded data from the object.

In accordance with one aspect of the disclosure, a method is provided for using a nuclear magnetic resonance (NMR) system. The method includes applying an off-resonance radio frequency (RF) pulse using a radio-frequency coil that is spatially inhomogeneous to induce a B₁-dependent resonant frequency shift in spins in a subject and, in the presence of the off-resonance RF pulse, applying a frequency-modulated, frequency-selective RF excitation pulse to spatially encode the spins in the subject. The method also includes acquiring NMR data from the subject that is spatially encoded and reconstructing the NMR data to produce a report of internal materials forming the subject.

In accordance with another aspect of the disclosure, a magnetic resonance imaging (MRI) system is provided that includes a magnet system configured to generate a polarizing magnetic field about a portion of the subject positioned in the MRI system. The MRI system also includes a radio frequency (RF) system configured to deliver RF pulses to the subject, and acquire therefrom magnetic resonance image (MRI) data and at least one processor. The at least one processor is configured to control the RF system to apply an off-resonance RF pulse using an RF coil of the RF system that is spatially inhomogeneous to induce a B₁-dependent resonant frequency shift in spins in the subject. The at least one processor is further configured to control the RF system to apply, in the presence of the off-resonance RF pulse, a frequency-modulated, frequency-selective RF excitation pulse to spatially encode the spins in the subject, control the RF system to acquire the MRI data from the subject that is spatially encoded, and reconstruct the MRI data to produce a report of internal materials forming the subject.

In accordance with another aspect of the disclosure, a method is provided for generating images or maps of a subject using a nuclear magnetic resonance (NMR) system. The method includes applying an off-resonance radio frequency (RF) pulse using a radio-frequency coil that is spatially inhomogeneous to induce a B₁-dependent resonant frequency shift in spins in a subject and, in the presence of the off-resonance RF pulse, applying a frequency-selective RF excitation pulse that is frequency modulated to correspond to a B₁ of interest to spatially encode the spins in the subject. The method also includes acquiring NMR data from the subject that is spatially encoded and reconstructing the NMR data to produce the images or maps of the subject

These and other advantages and features of the invention will become more apparent from the following detailed description of the preferred embodiments of the invention when viewed in conjunction with the accompanying drawings.

### BRIEF DESCRIPTION OF THE DRAWINGS

FIG. 1 is a schematic diagram of an example magnetic resonance imaging (MRI) system, in accordance with aspects of the present disclosure.

FIG. 2A is a graph illustrating traditional slice selection in MR imaging.

FIG. 2B is a graph illustrating a slice selection in accordance with the present disclosure.

FIG. 3 is a set of graphs that show the construction of a spatially-encoded excitation pulse in accordance with the present disclosure.

FIG. 4A is a graph showing magnetization profiles of varying off-resonance frequency offsets (ω_{off}) illustrating that increasing ω_{off} increases minimum pulse duration.

FIG. 4B is a graph showing that out-of-band excitation can be large and close to the excitation intended by the frequency-modulated, frequency-selective RF excitation pulse if ω_{off} is set too small.

FIG. 5A is a graph showing magnitude of a Bloch-Siegert-selective excitation (BSSE) inversion pulse in accordance with the present disclosure.

FIG. 5B is a graph showing motion of the net magnetization vector in the ω_{off} rotating frame for a stopband isochromat.

FIG. 5C is a graph showing motion of the net magnetization vector in the ω_{off} rotating frame for a passband isochromat.

FIG. 6A is a graph showing flip angle attenuation factor versus ω_{cent}/ω_{off}.

FIG. 6B is a graph showing an excited slice profile.

FIG. 7A is a set of graphs showing magnitudes of 90°, 180°, and 720° BSSE pulses with ω_{off}=7.5 kHz (702) and ω_{off}=10.0 kHz (700).

FIG. 7B is a set of graphs showing the corresponding simulated magnetization profiles to the magnetizations of FIG. 7A.

FIG. 8 is a pulse sequence in accordance with the present disclosure.

### DETAILED DESCRIPTION

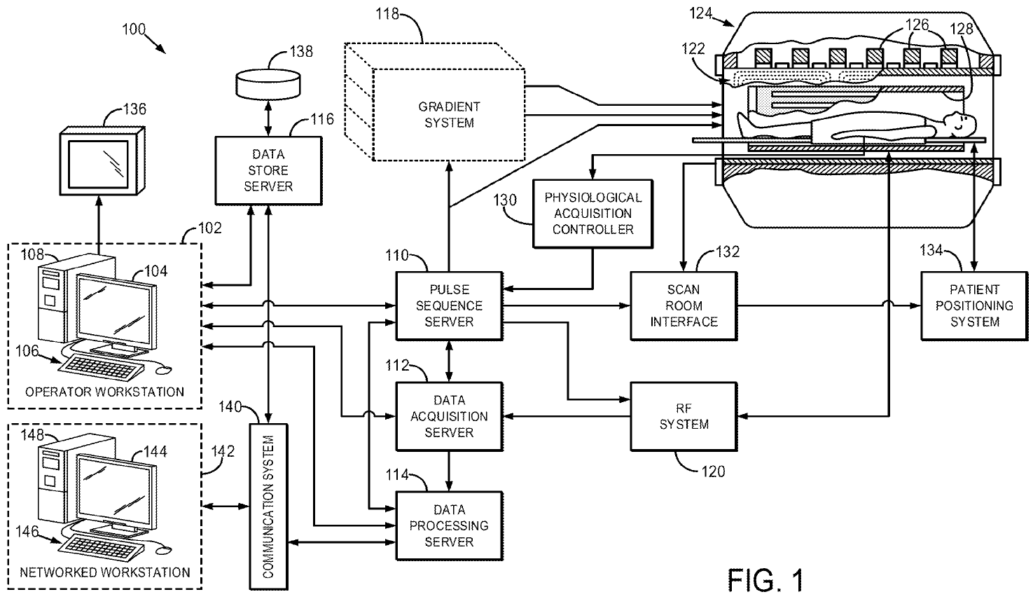

Referring to FIG. 1 a magnetic resonance imaging (MRI) system 100 in accordance with the present disclosure is illustrated. The MRI system 100 includes an operator workstation 102, which will typically include a display 104, one or more input devices 106 (such as a keyboard and mouse or the like), and a processor 108. The processor 108 may include a commercially available programmable machine running a commercially available operating system. The operator workstation 102 provides the operator interface that enables scan prescriptions to be entered into the MRI system 100. In general, the operator workstation 102 may be coupled to multiple servers, including a pulse sequence server 110; a data acquisition server 112; a data processing server 114; and a data store server 116. The operator workstation 102 and each server 110, 112, 114, and 116 are connected to communicate with each other. For example, the servers 110, 112, 114, and 116 may be connected via a communication system 140, which may include any suitable network connection, whether wired, wireless, or a combination of both. As an example, the communication system 140 may include both proprietary or dedicated networks, as well as open networks, such as the internet.

The pulse sequence server 110 functions in response to instructions downloaded from the operator workstation 102 to operate a radiofrequency (RF) system 120. Notably, the traditional gradient system 118 is indicated as optional because, using the systems and method described herein, the gradient system 118 may be entirely omitted or may be an optional system that is not generally needed. Correspondingly, a gradient coils assembly 122 to produce the magnetic field gradients Gₓ, G_{y}, G_{z} for position encoding magnetic resonance signals is likewise optional. Thus, the gradient coil assembly 122 may form part of a magnet assembly 124 that includes a polarizing magnet 126 and a whole-body RF coil 128, or the gradient coil assembly 122 may be omitted entirely and the RF system 120 and associated components may be utilized for spatial encoding, which substantially reduces the size, cost, and complexity of the MRI system 100.

That is, as will be described, the present disclosure provides systems and methods for utilizing the RF system 120 to perform spatial encoding that is traditionally performed with the gradient system 118 and associated components. In one non-limiting example, RF waveforms can be applied by the RF system 120 to the RF coil 128, or a separate local coil (not shown in FIG. 1), in order to perform the prescribed magnetic resonance pulse sequence, including B₁ spatial encoding.

Responsive magnetic resonance signals detected by the RF coil 128, or a separate local coil, are received by the RF system 120, where they are amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the scan prescription and direction from the pulse sequence server 110 to produce RF pulses of the desired frequency, phase, and pulse amplitude waveform. The generated RF pulses may be applied to the whole-body RF coil 128 or to one or more local coils or coil arrays.

The RF system 120 can include multiple RF transmit channels and may include multiple receiver channels. A given RF receiver channel includes an RF preamplifier that amplifies the magnetic resonance signal received by the coil 128 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²} Eqn. 1;

and the phase of the received magnetic resonance signal may also be determined according to the following relationship:

$$φ = {tan}^{- 1} ( \frac{Q}{I} ) . \qquad Eqn . 2$$

The pulse sequence server 110 also optionally receives patient data from a physiological acquisition controller 130. By way of example, the physiological acquisition controller 130 may receive signals from a number of different sensors connected to the patient, such as electrocardiograph (ECG) signals from electrodes, or respiratory signals from a respiratory bellows or other respiratory monitoring device. Such signals are typically used by the pulse sequence server 110 to synchronize, or “gate,” the performance of the scan with the subject's heartbeat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 does little more than pass the acquired magnetic resonance data to the data processor server 114. However, in scans that require information derived from acquired magnetic resonance data to control the further performance of the scan, the data acquisition server 112 is programmed to produce such information and convey it to the pulse sequence server 110. For example, during prescans, magnetic resonance data is acquired and used to calibrate the pulse sequence performed by the pulse sequence server 110. As another example, navigator signals may be acquired and used to adjust the operating parameters of the RF system 120, or to control the view order in which k-space is sampled. In still another example, the data acquisition server 112 may also be employed to process magnetic resonance signals used to detect the arrival of a contrast agent in a magnetic resonance angiography (MRA) scan. By way of example, the data acquisition server 112 acquires magnetic resonance data and processes it in real-time to produce information that is used to control the scan.

The data processing server 114 receives magnetic resonance data from the data acquisition server 112 and processes it in accordance with instructions downloaded from the operator workstation 102. Such processing may, for example, include one or more of the following: reconstructing two-dimensional or three-dimensional images by performing a Fourier transformation of raw k-space data; performing other image reconstruction techniques, such as iterative or backprojection reconstruction techniques; applying filters to raw k-space data or to reconstructed images; generating functional magnetic resonance images; calculating motion or flow images; resolving magnetic resonance fingerprinting (MRF) signal evolutions to reconstruct quantitative reports that include spatially-resolved measurements, maps, or images, and so on.

Images or reports reconstructed by the data processing server 114 are conveyed back to the operator workstation 102. Images or reports may be output to operator display 112 or a display 136 that is located near the magnet assembly 124 for use by attending clinician. Batch mode images or selected real-time images are stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The data processing server 114 may also be configured to reconstruct an image of the subject or generate a report about the subject. To this end, the data processing server 114 may include various computing capabilities, including various general-purpose processors, as well as various dedicated processing modules or logic (not shown in FIG. 1). For example, the data processing server 114 may include a module or logic that is configured to resolve the acquired MRF data. In one non-limiting example, the data processing server 114 may include a dictionary generating module or logic that is configured to identify quantitative information correlated to signal evolutions in MRF data, such as by comparing to a dictionary or via pattern matching, including machine or deep learning. That is, resolving MRF data or signal evolutions may be performed in various ways including, but not limited to, pattern matching, selection, minimization of a cost function, and optimization. Pattern matching may include, but is not limited to, orthogonal matching pursuit (OMP), categorical sequence labeling, regression, clustering, classification, real value sequence labeling, parsing algorithms, Bayesian methods, Markov methods, ensemble learning methods, and template matching. Optimization may include, but is not limited to, least squares optimization, regularized least squares optimization, basis pursuit optimization, and matching pursuit optimization. An optimization or matching process may be implemented using computer systems, including software algorithms, machine learning, or artificial intelligence, including neural networks. Other modules or logic for carrying out specific functions, as described herein, may also be possible. To this end, the data processing server 114 may be configured to access and retrieve data stored in a memory or other data storage location.

The MRI system 100 may also include one or more networked workstations 142. By way of example, a networked workstation 142 may include a display 144, one or more input devices 146 (such as a keyboard and mouse or the like), and a processor 148. The networked workstation 142 may be located within the same facility as the operator workstation 102, or in a different facility, such as a different healthcare institution or clinic. The networked workstation 142 may include a mobile device, including phones or tablets.

The networked workstation 142, whether within the same facility or in a different facility as the operator workstation 102, may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may be exchanged between the data processing server 114 or the data store server 116 and the networked workstations 142, such that the data or images may be remotely processed by a networked workstation 142. This data may be exchanged in any suitable format, such as in accordance with the transmission control protocol (TCP), the internet protocol (IP), or other known or suitable protocols.

Though described above with respect to “rooms” and, for example, a permanently installed MR system that is integrated into a particular physical location, such descriptions are non-limiting. For example, as will be described, the systems and methods described herein may be utilized with portable MR systems or mobile MR systems. In fact, as will be described, the systems and methods provided herein may further advance the practical application of smaller and truly mobile MR systems in clinical care.

In particular, as described above, there are a variety of undesirable aspects of dedicated gradient systems, such as described above. To address these issues with the use of dedicated gradient systems for applying B₀ gradients, alternative methods for B₀-gradient-free excitation localization and spatial encoding systems and methods have been considered.

The present disclosure recognizes that one alternative to the conventional B₀-phase encoding and frequency encoding gradients is to use a substantially, off-resonant RF pulse to induce a spatially dependent shift in the resonant frequencies of spins within an object to be imaged, while a frequency-selective excitation pulse is applied that is frequency modulated. For example, a substantially, off-resonant RF pulse to induce aB₁ dependent shift may be applied to exactly one region, or multiple adjacent regions with a variation within the range being, as one non-limiting example, less than 10%, or less than 9%, or less than 8%, or less than 7%, or less than 6%, or less than 5%, or less than 4%, or less than 3%, or less than 2%, or less than 1%. With the frequency- selective excitation pulse is applied that is frequency modulated applied superimposed, the B₁ may then vary by, for example, a factor of two, or greater. The present disclosure recognizes that this method of encoding can substitute for the phase encoding and frequency encoding B₀ gradients.

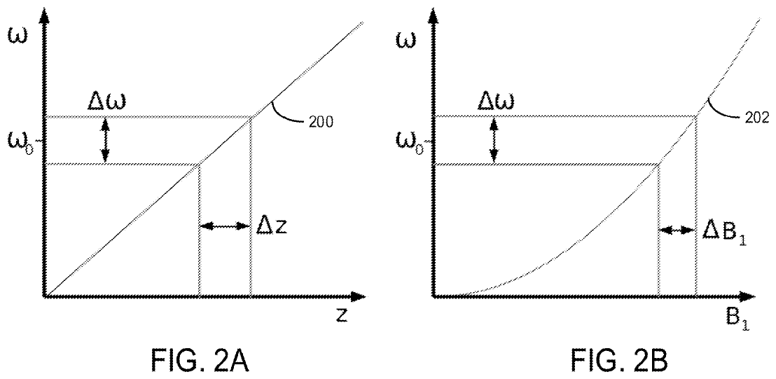

That is, spatially selective excitation is achieved in most magnetic resonance imaging scans using dedicated B₀ gradient coils. Objects under investigation are usually large and 3-dimensional (e.g., a patient), whereas the region from which signal is desired is typically restricted to a slice, slab, or limited volume. As described, conventional B₀-gradient-localized selective excitation is achieved by simultaneously playing out a slice-selective B₀ gradient, which induces a linear spatial variation in resonant frequency, and an RF pulse containing frequencies that map to locations in space where excitation is desired. That is, referring to FIG. 2A, in the one-dimensional case along the z-axis, a linear field gradient 200 superimposed on the main magnetic field produces a spatially-dependent shift in spins' resonant frequencies. Simultaneously applying an RF pulse with a frequency passband width Δω from a transmit coil with a homogeneous transmit field selectively excites spins within a spatial width Δz, where Δω and Δz are related through the strength of the gradient. That is, when paired with a frequency-selective excitation pulse with center frequency ω₀ and bandwidth Δω, a spatial slice of thickness Δz is excited.

On the other hand, as will be described, the present disclosure provides systems and methods where RF pulses can be used for spatial encoding. Advantageously, B₁ gradients can be switched in near-negligible time without acoustic noise, eddy currents, or peripheral nerve stimulation resulting from large dB/dt. However, replacing B₀ gradients with RF magnitude gradients in an imaging system introduces new challenges, such as devising ways to spatially localize excitation utilizing only the RF transmit field.

A number of methods exist that attempt to exploit an inhomogeneous transmit field for spatial discrimination, such as early techniques for localized spectroscopy in B⁺ gradients utilizing composite 180° hard pulses. These pulse trains achieve a rudimentary degree of spatial localization, but require multiple free induction decay (FID) acquisitions to define the region of interest (ROI) and do not provide strict profile definition. Another approach, the related depth pulse sequence technique, requires a smaller number of FID acquisitions and is somewhat more robust to off-resonance than composite pulses, but similarly provides only minimal control over the excitation profile. A third method proposed by Hoult is rotating-frame B₁-selective excitation (RFSE) by means of an RF pulse with constant B_{1,x} and modulated B_{1,y}. These pulses selectively excite magnetization based on the strength of the B_{1,x} component. The selectivity of the rotating frame method was improved over time, and a later recasting of the problem as a rotated Shinnar-Le Roux (SLR) design enabled pulse designers to meet target slice profile characteristics in B₁. Although these advances were able to provide fine control of the excitation profile, these pulses face some practical challenges, including unintended excitation at low B₁ with off-resonance and sensitivity to RF amplifier distortions due to the pulses' strict envelope area requirements.

Unlike these attempts to use inhomogeneous transmit fields to provide spatial information, the present disclosure provides a robust alternative for spatial encoding that overcomes these drawbacks. That is, a substantially, off-resonant RF pulse can be used to induce a spatially dependent shift in the resonant frequencies of spins within an object to be imaged. Then the frequency-selective excitation pulse is applied over the off-resonant RF pulse.

In one non-limiting example, the far-off-resonant pulse may be the so- called Bloch-Siegert (BS) pulse. The Bloch-Siegert shift has not been applied as a substitute for the conventional B₀ slice-select gradient. As will be described, a new class of RF pulses is provided that can utilize a Bloch-Siegert shift (or other shift) to produce a selective excitation that can be used for spatial encoding without the use of B₀ gradients.

Irradiation of a nucleus with an off-resonant RF pulse induces a shift in the frequency of this precession dependent on the magnitude of the RF field the nuclei experience. This effect can be referred to as the Bloch-Siegert shift. The present disclosure recognizes that the Bloch-Siegert shift produces a one-to-one correspondence between nuclei's precession frequencies and B₁, analogous to how a conventional B₀ gradient used in modern, conventional MRI produces a correspondence between a nuclei's precession frequency and space. In conventional MRI, the frequency-to-space correspondence produced by B₀ gradients is the basis of signal localization and is fundamental to the ability to create an image from the signals measured from the body.

Building upon the recognition of the one-to-one resonant frequency-to-B₁ relationship produced by a Bloch-Siegert pulse, the present disclosure further recognizes that, if a Bloch-Siegert pulse and an excitation RF pulse that is modulated to a frequency corresponding to a B₁ of interest are simultaneously applied, the system is able to selectively excite spins that experience a transmit field strength corresponding to the frequency modulation of the excitation pulse. Notably, these pulses do not need to be applied exactly simultaneously. For example, one can break up both the BS and excitation pulses into sub-pulses (via smaller time segments) and alternately apply those sub-pulses, such that one can select another spatial dimension with the excitation sub-pulse. In this way, the systems and methods described herein could even be used in the presence or in coordinate with using conventional B₀ gradients. As an alternative to the two sub-pulses being on simultaneously as described above, the Bloch-Siegert pulse may be switched on and present in the background through the gradient coil, while the excitation pulse is played out at different points in time.

Thus, the desired encoding may be achieved by summing a Bloch-Siegert pulse, which establishes a frequency gradient across B₁, and a frequency-selective excitation pulse shape containing frequencies that map to the desired range of B₁'s to be excited. The result is a B₁-selective excitation. That is, referring to FIG. 2B, a Bloch-Siegert shift-localized slice selection, in which an off-resonant RF pulse produces an approximately quadratic variation in resonant frequencies across field strengths B₁ 202. When paired with a frequency-selective excitation pulse, this results in the excitation of spins across a range of B₁, which can be mapped to space using an amplitude gradient transmit coil, as will be described. Thus, a B₁-selective excitation is created that is localized by the far-off-resonance pulse, which may induce a Bloch-Siegert shift. The approximately quadratic relationship between frequency and B₁ is determined by the instantaneous off-resonance frequency of the far-off-resonance pulse, while the range of B₁ excited is determined by the frequency content of the superimposed excitation pulse.

Notably, neither the BS pulse nor the excitation pulse will produce a substantially selective excitation if played out independently. More particularly, the BS pulse may produce negligible excitation. On the other hand, the excitation pulse could produce excitation because it will be closer to resonance, but the excitation produced by the excitation pulse alone would not be selective. However, the superposition of the BS and excitation pulses is able to produce a selective excitation, where the B₁ selectivity is dependent on the frequency modulation of both pulses. If the RF transmit coil playing out the BS or superimposed excitation pulse has a spatially inhomogeneous B₁ transmit field, the pulse will result in a spatially selective excitation, because the transmit field will vary with space. Spatially selective excitations are desirable for imaging of slices of anatomy in, for example, anatomical MRI or voxels of interest in MR spectroscopy.

In accordance with the present disclosure, the Bloch-Siegert pulse may be a swept off-resonance pulse. It may be, for example, an adiabatic half-passage (AHP) pulse followed by a constant-frequency pulse, followed by a time-reversed AHP pulse. In one non-limiting example, this pair of AHP pulses may be formed as a frequency sweep from far off-resonance to a constant off-resonant value, then back out; and an amplitude sweep from 0 to the maximum amplitude then back down to 0. This frequency and amplitude swept pulse can be used to maximize the frequency shift while minimizing in-band excitation. The excitation pulse may be, for example, a Shinnar Le-Roux (SLR) excitation pulse modulated to a constant offset frequency. In order to compensate for the drop-off in B₁ magnitude over the range of B₁'s corresponding to the bandwidth of the SLR pulse, a custom SLR beta filter that allows for the design of a ramped magnetization profile may be used. This produces an approximately flat passband over a range of B₁'s of interest. However, it is noted that there is wide latitude in the choice of both Bloch-Siegert pulse and frequency-selective excitation pulse. Other types of pulses such as inversions, saturations, or non-analytic pulses could also be used in place of the “excitation” pulse, which could be designed using SLR, optimal control, the inverse scattering transform or any other method that allows the pulse to have a frequency modulation that maps frequency to a selected B₁. Other off-resonant Bloch-Siegert pulses could be used as well, as long as they are sufficiently far off-resonance and produce a sufficiently large variation in resonant frequencies. Irrespective of the design or type of the two pulses, the far-off-resonance pulse is satisfactory if it induces a B₁-dependent resonant frequency shift and the excitation pulse is satisfactory if it is frequency modulated to correspond to a B₁ of interest.

Thus, the present disclosure provides systems and methods to create and use B₁- selective pulses formed as the summation of 1) a far-off-resonant, frequency-shift-inducing pulse, and 2) a frequency-selective excitation pulse. The two pulses work in together to achieve the encoding otherwise achieved only with the paired B₀ z-gradient and frequency-selective excitation pulse used in conventional imaging slice selection. The far-off-resonance RF pulse, may be a Bloch-Siegert pulse, creates a nonlinear frequency gradient that varies with B₁.

The primary resonance used for excitation in this framework can be the Bloch Siegert-shifted single-photon resonance, initially at the Larmor frequency before being shifted. This new pulse class is reliant on the simultaneous application of two off-resonant pulses in the x-y plane, which also produces additional multiphoton resonances.

In the following, the design of the two component pulses that make up a localized B₁-selective excitation pulse is described. Although there are many feasible choices for both the off-resonant pulse and the frequency-selective pulse, one non-limiting example of a combination of an amplitude- and frequency-swept off-resonant pulse and an SLR frequency-selective pulse is provided. This combination allows the designer to directly specify and analytically trade off pulse and B 1 profile parameters.

Design of these two pulses is analytic, efficient, and fast. Simulations show the pulses' suitability for selective excitation, inversion, and refocusing. Off-resonance behavior is simulated and shown to be predictable and similar to that of conventional spatially slice-selective excitation pulses, without the out-of-band excitation produced by the RFSE pulses discussed above.

The design of a far-off-resonance pulse will be described with respect to a non-limiting example. In particular, the pulse will be described with respect to a Bloch-Siegert B₁-selective excitation (BSSE) pulse that is formed from the design of two distinct component pulses: 1) an off-resonant pulse, b_{bs}(t) , which produces a B₁-dependent shift in resonant frequencies via the Bloch-Siegert effect, and 2) a frequency-selective SLR pulse, bₑₓ(t) , which excites a desired B₁ passband. Although these two pulses could be transmitted by separate coils, for this example, they are generated together by the same transmit coil, so they are complex-summed once individually designed, as given by:

bₜₒₜₐₗ(t)=b_{bs}(t)+bₑₓ(t) Eqn. (3).

Again, however, this is only provided for exemplary purposes and is non-limiting. Turning first to component pulse 1 of this non-limiting example, the Bloch-Siegert Shift-inducing pulse will be described. In the absence of externally applied RF, the magnetic resonance frequency is the Larmor frequency, ω₀=γB₀. If an RF field is applied with amplitude B₁⁺ and frequency offset co bff relative to ω₀, then a Bloch-Siegert frequency shift of the resonance is produced, given by:

$${ω}_{bs} ( {B}_{1} , {ω}_{off} ) \approx - {ω}_{off} ( \sqrt{1 + {( \frac{γ {B}_{1}}{{ω}_{off}} )}^{2}} - 1 ) . \qquad Eqn . ( 4 )$$

This shift is away from the frequency of the applied off-resonance RF. That is, an RF pulse with a positive ω_{off} results in a negative ω_{bs}. The Bloch-Siegert shift-inducing pulse is defined as an amplitude- and phase-modulated function given by:

b_{bs}(t)=A_{bs}(t)e^{iφ}^{_{bs}}^{(t)} Eqn. (5);

where φ_{bs}(t)=∫_{-T/2}^{t}Δω_{rf}(t′)dt′ is the time integral of the pulse's time-varying frequency modulation Δω_{rf}(t), and T is the pulse duration. For A_{bs}(t), a Fermi pulse is used to produce a large Bloch-Siegert frequency shift with little out-of-band excitation. The Fermi envelope provides an additional benefit for this application because its plateau results in a constant ω_{bs} for the majority of the pulse duration, which simplifies the design of the bₑₓ(t) pulse so long as bₑₓ(t) is restricted to be nonzero only on the plateau. Thus, for A_{bs}(t) anormalized Fermi pulse is used which is centered at t=0, such that:

$${A}_{bs} ( t ) = \frac{1}{1 + {e}^{\frac{\vert t \vert - {t}_{0}}{a}}} ; \qquad Eqn . ( 6 )$$

where t₀ and α are parameters with units of seconds that control the duration of the pulse and the width of the transition, respectively. The duration of this Fermi pulse is T=2t₀+13.81α. To ensure that bₑₓ(t) is only nonzero during the plateau when A_{bs}(T)≈1, Eqn. 6 is used such that t₀ should be set to:

$${t}_{0} = \frac{{T}_{ex}}{2} - a ln ( \frac{1}{{A}_{th}} - 1 ) ; \qquad Eqn . ( 7 )$$

where Tₑₓ is the duration of bₑₓ(t) required to excite the desired bandwidth and Aₜₕ is a user-specified constant. This t₀ setting creates a central plateau in the Fermi envelope of duration Tₑₓ with A_{bs}(t) ≥Aₜₕ. Herein, all pulse designs used α=6×10⁻⁵ and Aₜₕ=0.95 although other parameter combinations are possible.

A modification is made to the conventional constant frequency-offset Fermi by starting and ending the pulse's FM waveform far-off resonance and sweeping adiabatically towards and away from the central constant frequency offset ω_{off}. This modification spin-locks the magnetization during the Fermi's amplitude sweeps, reducing undesired excitation by A_{bs}(t). The analytic adiabatic sweep can be modified to allow for time-varying A_{bs}(t). The first half of the symmetric frequency sweep is given by:

$$Δ {ω}_{sweep} ( t ) = \frac{γ {A}_{bs} ( t )}{\sqrt{{( 1 - \frac{γ {A}_{bs} ( t )}{K} t )}^{- 2} - 1} r} , t ∈ ( 0 , T / 2 ) , \qquad Eqn . ( 8 )$$

where T is the duration of the full A_{bs}(t) waveform and K is a design parameter which trades off the maximum offset of the frequency sweeps and undesired excitation by A_{bs}(t). In one non-limiting example, K=0.2 was used for all pulses, which produces a maximum frequency offset of ˜10-30 kHz for a practical ω_{off} range of 5-20 kHz. The full FM waveform with constant frequency plateau ω_{off} is then given by:

$$Δ {ω}_{rf} ( t ) = \{ \begin{matrix}- Δ {ω}_{sweep} ( t + T / 2 ) + max ( Δ {ω}_{sweep} ( t ) ) + {ω}_{off} , & - T / 2 < t < 0 , \\ - Δ {ω}_{sweep} ( T / 2 - t ) + max ( Δ {ω}_{sweep} ( t ) ) + {ω}_{off} , & 0 \leq t < T / 2\end{matrix} . \qquad Eqn . ( 9 )$$

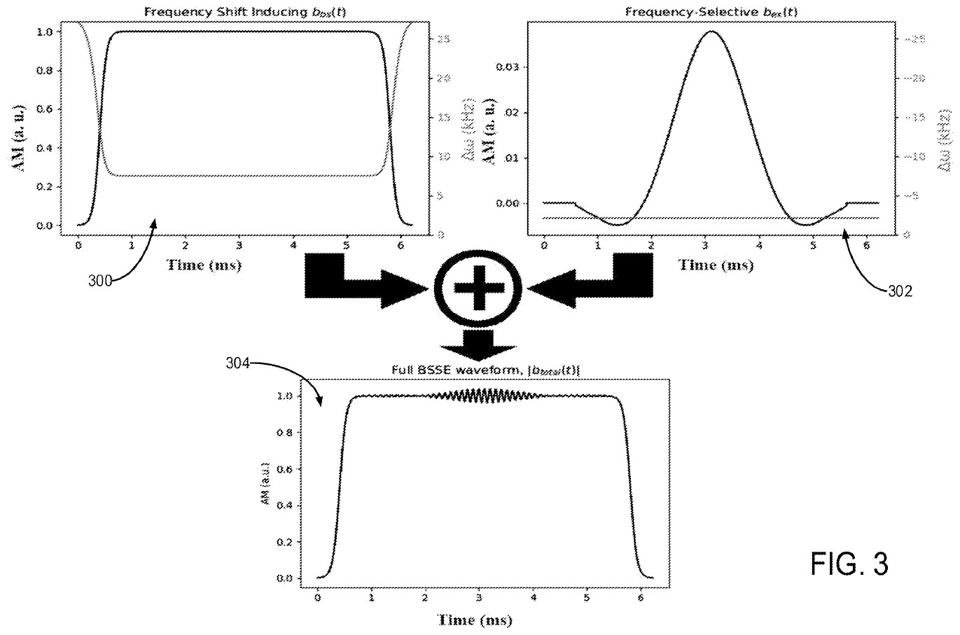

An example of an amplitude- and frequency-modulated b_{bs}(t) 300 is shown in FIG. 3. Note that the frequency modulation of this pulse is positive for all t, producing a negative Bloch-Siegert frequency shift for all B₁⁺. As a result, the frequency-selective excitation pulse described in the next section is modulated to a negative frequency relative to Larmor, to excite the desired B_{1passband}.

Next is the second component pulse, which is a frequency-selective excitation pulse. In this non-limiting example, the frequency-selective excitation pulse may be a Shinnar Le-Roux (SLR) pulse, though a variety of other pulses may be used.

For a given desired passband between field strengths B_{1,L} and B_{1,H}, the bandwidth of resonant frequencies that must be excited by the frequency-selective pulse bₑₓ(t) can be given by:

B=ω_{bs}(B_{1,L},ω_{off})−ω_{bs}(B_{1,H},ω_{off}) Eqn. (10);

where bₑₓ(t) can be frequency modulated to the center of the passband, which has frequency:

ω_{cent}=1/2(ω_{bs}(B_{1,L},ω_{off})+ω_{bs}(B_{1,H},ω_{off}) Eqn. (11).

An SLR pulse design algorithm can be used to design bₑₓ(t) since it allows for direct design of pulses to meet design constraints including bandwidth (B) , duration (Tₑₓ) , flip angle (θ), transition width, and magnetization profile ripple (δ₁^{e} and δ₂^{e}). Based on these parameters, SLR design can be used to identify a pair of polynomials that are transformed to the discretized excitation pulse by the inverse SLR transform. Given the designer's choice of time-bandwidth product TₑₓB, the duration of the excitation pulse Tₑₓ can be determined by B. The RF pulse output by SLR design can be interpolated to the target dwell time and can be scaled to produce the desired flip angle θ for the B₁ at its passband center, based on the relationship:

θ=γΔₜB₁⁺(ω_{cent})Σᵢ₌₀^{N-1}Aₑₓ(tᵢ) tm Eqn. (12);

where Δₜ is the dwell time, N is the number of time points in the pulse, and Aₑₓ(t) is the baseband RF pulse waveform generated by SLR after interpolating it to the target dwell time. B₁(ω_{cent}) is derived from Eqn. 4 after rearranging it to give the B₁ producing a Bloch-Siegert shift of ω during an RF pulse with frequency offset ω_{off}>0:

$${B}_{1} ( ω ) \approx \frac{{ω}_{off}}{γ} \sqrt{{( 1 - \frac{ω}{{ω}_{off}} )}^{2} - 1} . \qquad Eqn . ( 13 )$$

After scaling Aₑₓ(t) to the desired flip angle, bₑₓ(t) can be obtained by frequency modulating it to ω_{cent}. The final pulse can then be given by:

bₑₓ(t)=Aₑₓ(t)e^{iω}^{_{cent}}^{t} Eqn. (14).

Before summing bₑₓ(t) with b_{bs}(t), bₑₓ(t) can be zero-padded to match the full duration T of b_{bs}(t). An example bₑₓ(t) 302 for TₑₓB=4 and θ=90° is shown in FIG. 3. A summation of these pulses 304 is also illustrated in FIG. 3.

However, under the assumption that both bₑₓ(t) and bₜₒₜₐₗ(t) are played from the same transmit coil, bₑₓ(t) will produce a sloped magnetization profile (or a distorted profile, in the case of 180° excitation) due to the fact that bₑₓ(t) is played out slightly weaker than designed at passband locations where B₁+<B₁ (ω_{cent}) and slightly stronger than designed where B₁>B₁ (ω_{cent}). The degree of distortion will depend on the width of the passband relative to its center, (B_{1,H}−B_{1,L})/B₁ (ω_{cent}), and can, therefore, be more pronounced for wide passbands and center positions closer to zero.

This process can be modified to correct for these distortions. For example, the SLR design algorithm can be modified to compensate for a sloped excitation profile across B₁. The process can begin with the selection of a desired magnetic profile parameters and performing a design process 400. In the case of small-tip (‘st’) or 90° (‘ex’, ‘sat’) excitation, a pointwise scaling of the B_{N}(ω) profile may be sufficient. For an inversion (‘Inv’) or refocusing (‘se’) pulse, iterative refinement may be required.

That is, for small-tip and 90° excitation, the distortion is approximately compensated by scaling the SLR algorithm's B N (w) polynomial by the inverse of the transmit field strength corresponding to each frequency co in the profile, with normalization to B₁(ω_{cent}) , prior to applying the inverse SLR transform:

$${B}_{N} ( ω ) ← \frac{{B}_{1} ( {ω}_{cent} )}{{B}_{1} ( ω + {ω}_{cent} )} {B}_{N} ( ω ) . \qquad Eqn . ( 14 )$$

For 180° inversion or refocusing, profile distortion cannot be corrected with this analytic method. Instead, an iterative optimization of the RF pulse can be used to alleviate profile distortion caused by varying B₁, as will be further described.

Turning to the overall pulse design procedure, a first step may be to select the B₁ passband edges B_{1,H} and B_{1,L}, the excitation pulse's SLR algorithm parameters, and flip angle, and the BS pulse's frequency offset co off. With these parameters, the SLR pulse can be designed, interpolated to the target dwell time, scaled to the desired flip angle, and frequency modulated to the center frequency W cent of the slice, yielding the pulse bₑₓ(t). Knowing the duration Tₑₓ of bₑₓ(t), the BS pulse b_{bs}(t), can be calculated. bₑₓ(t) can be zero-padded to the same length as b_{bs}(t), and the two pulses can be complex-summed to obtain the total pulse bₜₒₜₐₗ(t)=b_{bs}(t)+bₑₓ(t).

An arbitrary value can be selected for the flip angle, avoiding 90 or 180, to produce a range of in homogenous values of the B₁ field. Notably the range of flip angles in a given field of view is less than the range in the B₁ field. The on-resonance excitation pulse has a complex value, as described above. Thus, an arbitrary flip angle and phase is achieved as a function of the B₁ field.

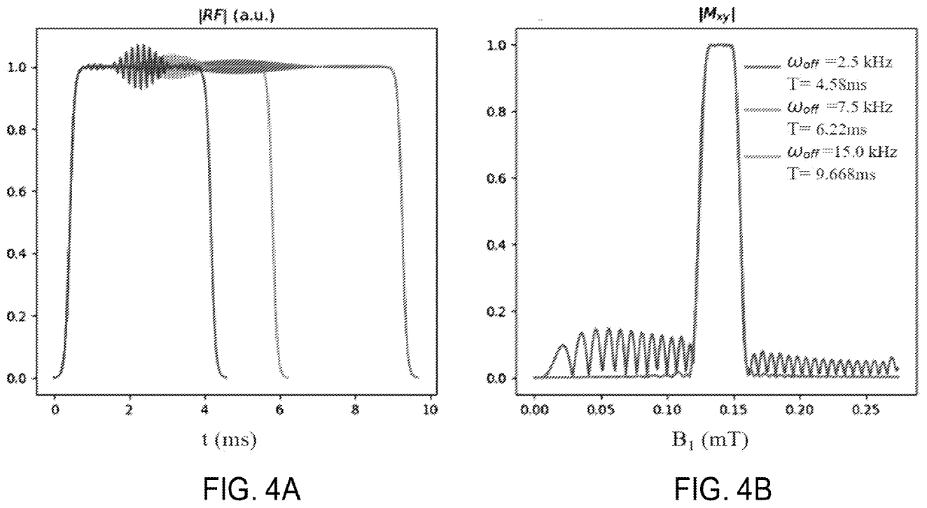

It is noted that the choice of ω_{off} can be important to the performance of the pulse. For example, referring to FIGS. 4A and 4B, decreasing ω_{off} also decreases pulse duration by increasing the Bloch-Siegert frequency gradient, but bringing ω_{off} too close to the Larmor resonance produces out-of-band excitation. That is, FIGS. 4A and 4B provide a comparison of magnetization profiles produces by BSSE pulses with varying ω_{off}. Referring to FIG. 4A, increasing ω_{off} increases minimum pulse duration, due to the reduced bandwidth produced by the smaller Bloch-Siegert shift across B 1. Referring to FIG. 4B, out-of-band excitation can be large if ω_{off} is set too small. A pulse with ω_{off}=2.5 kHz produces a substantial amount of out-of-band excitation, which is reduced to within design specifications when ω_{off}7.5 kHz. Continuing to increase ω_{off} to 15.0 kHz did not further improve the profile.

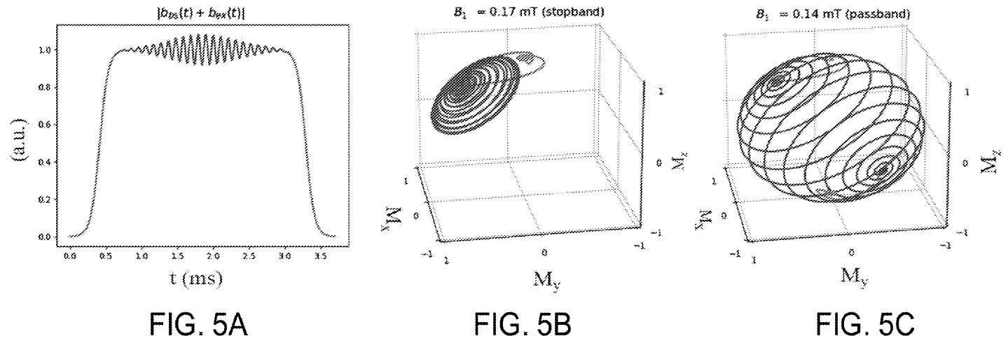

Motion of the magnetization vector may also be considered. With the full BSSE waveform defined, the trajectory of a magnetization vector \vec{M} during application of a BSSE RF pulse bₜₒₜₐₗ(t) can be described. The motion of the normalized magnetization vector \vec{M} can be visualized, as illustrated in FIGS. 5A-5C, in a frame rotating at ω_{off} for spin isochromats in B₁ fields, for example, at 0.17 mT (in the stopband) and at 0.14 mT (in the passband), respectively. During the first adiabatic sweep of the RF pulse, both magnetization vectors rotate down from equilibrium to an axis that is slightly tilted away from the x-y axis. At the end of the initial sweep, when |bₜₒₜₐₗ(t)|≈|b_{bs}(t)| and Δω_{rf}(t)≈ω_{off}, \vec{M} is approximately colinear with the tilted effective field:

\vec{B}=[γB₁ 0ω_{off}]/γ Eqn. (15);

at which point the frequency-selective bₑₓ(t) pulse begins. For the stopband isochromat of FIG. 5b this pulse is not resonant, but it is resonant with the isochromat of FIG. 5C and the magnetization is nutated by the component of bₑₓ(t) perpendicular to \vec{B} to the opposite side of the unit sphere. After bₑₓ(t) is completed, the second adiabatic frequency sweep returns \vec{M} to being approximately colinear with the main magnetic field. The stopband isochromat in FIG. 5B is aligned and approximately unperturbed from equilibrium, while the passband isochromat of FIG. 5C is successfully inverted.

The above-described process can be used to compensate for flip angle errors. The pulse design algorithm described above is based on the implicit approximation that the effect of applying b_{bs}(t) is to produce a pure B₁-dependent resonance frequency shift. In reality, as illustrated in FIGS. 5A-5C, b_{bs}(t) rotates magnetization to precess in a plane that is slightly tilted from the x-y plane, at an angle

$${tan}^{- 1} ( \frac{γ {B}_{1}^{+}}{{ω}_{off}} )$$

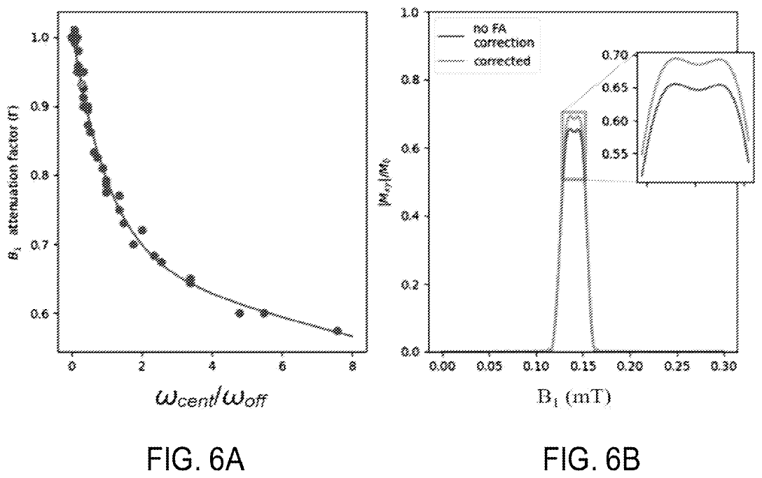

from the z-axis. Ideally, bₑₓ(t) would also be applied in this tilted plane, but it remains in the x-y plane, and the actual flip angle produced by bₑₓ(t) will be slightly smaller than expected because its projection onto the tilted plane will be elliptical and smaller than its full amplitude. This results in a flip angle attenuation that increases as ω_{cent}/ω_{off} becomes large. Similar effects have been previously observed in other dual-frequency RF applications. Given the difficulty of describing and correcting this effect analytically, a normalized empirical correction is given herein for the amplitude of Aₑₓ(t) based on Bloch simulations of slice profiles across a wide range of ω_{cent} and ω_{off}. The model is shown in FIG. 6A.

In particular, the models used to correct for flip angle inaccuracy is as follows. The observed flip angle attenuation was fit by a biexponential model, using MATLAB's fit [] function. This attenuation model is given by I″(x)=0.335e^{-1.116x}+0.678e^{-0.028x}, where x=ω_{cent}/ω_{off}. The correction is applied by accounting for I″(x) in the flip angle relation of Eqn. 12, such that θ=γΔₜI′(x)B₁ (ω_{cent}) Σᵢ₌₀^{N-1} Aₑₓ(ti). The goodness-of-fit of this model was R²=0.9899.

Deviations are generally small and require minimal correction for pulses where ω_{cent}/ω_{woff}<1 as suggested by the example profile correction shown in FIG. 6B. This comprises the majority of practical BSSE pulses. Pulses withω_{cent} substantially larger than ω_{off} are in general encountered when designing a pulse to select a PBC at very large B₁ (which produces a large Bloch-Siegert shift and thus large ω_{cent} relative to ω_{off}), or when a very small ω_{off} is used, which is typically impractical due to the large out-of-band excitation produced.

As discussed, the simultaneous application of two off-resonance RF pulses in BSSE excitation leads to non-linear effects including small flip angle errors. A second effect is the appearance of subsidiary multiphoton resonances, in addition to the single-photon resonance. These are a consequence of the BSSE pulse's simultaneous irradiation of nuclei at two frequencies near (generally within 10's of kHz) but not at the Larmor frequency. While unwanted higher-order multiphoton resonances cannot be corrected simply by adjusting the bₑₓ(t) pulse's amplitude or frequency, their positions can be predicted analytically as follows and used to guide the pulse design.

The off-resonance frequencies of the two component pulses bₑₓ(t) and b_{bs}(t) are ω_{cent} and ω_{off}, with an average frequency of the two off-resonant pulses ωₐᵥ=1/2(ω_{cent}+ω_{off}) Multiphoton resonances occur at frequencies ω₀,N for which the following is satisfied:

$$\frac{{ω}_{1} - {ω}_{av}}{{ω}_{0 , N} - {ω}_{av}} \vert \approx \frac{1}{N} , N = 1 , 3 , 5 , … ; \qquad Eqn . ( 16 )$$

where ω₁ is equivalently either ω_{off} or ω_{cent}. N=1 corresponds to the single-photon resonance while N=3,5,7 . . . correspond to multiphoton resonances. Arbitrarily taking ω₁=ω_{off}, two solutions exist for ω_{0,N}:

ω_{0,N}≈ωₐᵥ±N(ω_{off}−ωₐᵥ) Eqn. (17).

In this application, becauseω_{off}>0 will produce a negative frequency shift for all B 1, only ω_{0,N}>0 are of interest. These resonances are given by the solution ω_{0,N}≈ωₐᵥ+N(ω_{off}−ωₐᵥ). To determine the locations of the multiphoton resonances on the B₁⁺ axis, we can substitute Eqn. 17 into Eqn. 13, giving:

$${B}_{1 , mp}^{+} ( N , {ω}_{av} , {ω}_{off} ) \approx \frac{{ω}_{off}}{γ} \sqrt{{( 1 - \frac{{ω}_{av} + N ( {ω}_{off} - {ω}_{av} )}{{ω}_{off}} )}^{2} - 1} , \qquad Eqn . ( 18 )$$

$$N = 1 , 3 , 5 , … .$$

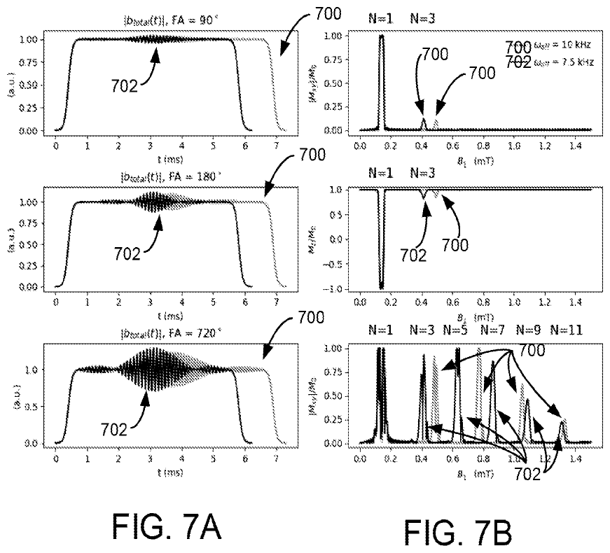

Pulses with two combinations of ω_{off} and ω_{cent} but with the same PBC for the N=1 excitation are shown in FIG. 7A. In particular, the pulses 700 have (ω_{off}=10 kHz and ω_{cent}=−1.655 kHz , and the pulses 702 have (w_{off}=7.5and ω_{cent}=−2.094 kHz. FIGS. 7A and 7B show the distribution of multiphoton resonances across B₁ for the two ω_{off}. For both ω_{off}, the combination of RF frequencies place the N=1 resonance at 0.14 mT. For the 90° and 180° pulses there isasmall amount of excitation produced at the N =3 resonance (maximum |M_{xy}|M₀=0.075 for the excitation and maximum M_{z}/M₀=0.918 for the inversion), but excitation at N>3 is below the stopband ripple level of the pulses. In the case of the pulse scaled up to produce a 720° flip, agreater number of multiphoton resonances can be appreciated. These simulated resonances shown in FIG. 7B are at the approximate locations predicted by Eqn. 18. In the case of the black pulse ((ω_{off}=7.5 ), the resonances (aside from N=1) are at B_{1,mp}⁺=[0.14,0.41, 0.65, 0.88, 1.11, 1.34 ]mT. In the case of pulse 700 (ω_{off}=10 kHz), the predicted locations of the N=1 to 11 resonances shift up to B_{1,mp}=[0.14,0.49,0.79,1.07,1.35,1.62 ]mT. Using a larger ω_{off} can shift multiphoton resonances upward in B₁ and out of the imaging bandwidth, although this decreases the Bloch-Siegert frequency gradient and thus needs longer pulse durations.

### EXAMPLE—SIMULATIONS

Simulations were performed to demonstrate the effectiveness of SLR B_{N}(ω) ramp correction, to evaluate the pulses' suitability for refocusing in an RF gradient slice-selective Carr-Purcell-Meiboom-Gill (CPMG) pulse sequence, and to compare their performance across B₁ and off-resonance to that of RFSE B₁- selective excitation pulses. All simulations were performed using a hard pulse approximation-based Bloch simulator, as described in Pauly J, Nishimura D, Macovski A, Roux P L. Parameter Relations for the Shinnar-Le Roux Selective Excitation Pulse Design Algorithm. IEEE Transactions on Medical Imaging 1991; 10:53-65, in SigPy.RF Martin J, Ong F, Ma J, Tamir J, Lustig M, Grissom W. SigPy.RF: Comprehensive Open-Source RF Pulse Design Tools for Reproducible Research. In: Proc. Intl. Soc. Mag. Reson. Med. 28th Annual Meeting, 2020. p. 1045, with 1 μs dwell time. All BSSE and RFSE pulses were designed using SigPy.RF pulse design functions.

Profile Ramp Correction

Simulations were performed to verify the ability of the BSSE ramp correction algorithm to correct passband distortions caused by varying B₁. A 30° small-tip pulse, a 90° excitation pulse, and a 180° inversion pulse were constructed and their magnetization profiles were simulated across B₁. For all three pulses, PBC=0.14 mT, PBW=0.06 mT, TₑₓB=8, d₁^{e}=d₂^{e}=0.01, ω_{off}=7.5 kHz ; these parameters were chosen to create a profile in which uncorrected distortions were clearly visible. In profiles with smaller TₑₓB or PBW, the distortion is not easily observable. The small-tip and 90° excitation pulses were designed using the analytic B_{N}(107 ) ramp correction. In the inversion case, an uncorrected BSSE inversion pulse was designed to meet the profile parameters specified above as well as possible. This pulse was used as the initializer for an iterative gradient descent refinement to eliminate distortions. The following general unconstrained problem was solved:

min Σᵢ₌₀^{N}^{_{b}}⁻¹wᵢ|M_{z}(bₜₒₜₐₗ,B_{1,i})−M_{z,d}(B_{1,i}⁺)|² Eqn. (19);

where {M_{z}(bₜₒₜₐₗ,B_{1,i})}ᵢ₌₀^{N}^{_{b}}⁻¹ is the Bloch-simulated M_{z} profile of the BSSE pulse vector btotal bₜₒₜₐₗ across transmit field strengths {B_{1,i}}ᵢ₌₀^{N}^{_{b}}⁻¹, and {M_{z,d}(B₁)}ᵢ₌₀^{N}^{_{b}}⁻¹ is the desired inversion profile across the same B_{1range}. The {wᵢ} are error weights used to specify the transition regions of the profile as “don't care” regions for the optimization. The gradient of the loss was calculated across a grid of 250 points in B₁ from 0 to 0.25 mT using an automatic differentiation function from the JAX software toolbox described at Martin J, Ong F, Ma J, Tamir J, Lustig M, Grissom W. SigPy.RF: Comprehensive Open-Source RF Pulse Design Tools for Reproducible Research. In: Proc. Intl. Soc. Mag. Reson. Med. 28th Annual Meeting, 2020. p. 1045. Gradient descent steps were taken to control this loss, with afixed step size of 1e-4. Iterations were performed until convergence, defined as a difference in loss between iterations of less than 1%.

The improved small-tip excitation, 90° excitation, and inversions with ramp correction were achieved in the simulations. The small-tip excitation had a substantial ramp across B₁ when uncorrected which was flattened by the analytic correction, with differences between normalized |M_{xy}|M₀ at passband edges reduced from 0.0893 in the uncorrected case to less than 0.001 in the corrected case. The 90° excitation also had substantially reduced distortion in the passband, particularly on the rising edge of the profile. Iterative optimization of the inversion pulse reached convergence after 37 gradient descent iterations. The final optimized pulse produced a substantially improved magnetization profile which met the desired ripple levels (d₁^{e}=d₂^{e}=0.01) and transition width. The substantial ripple produced by over-flipping on the falling edge of the profile was eliminated, and the broad transition on the rising edge of the profile was sharpened.

Off-Resonance Simulation

Four BSSE pulses and four RFSE pulses were designed, with ω_{off} of the BSSE pulses set to give the pulses the same duration as the RFSE pulses. The “base” pulse for both pulse classes was a 6.27 ms TₑₓB=4 pulse at 90° flip angle, centered at PBC=0.4 mT with PBW=0.03 mT and M_{xy} passband and stopband maximum errors of of δᵢ^{e=δ}₂^{e}=0.01. The other three pulses each had one parameter changed from the base pulse (Pulse 1): Pulse 2 had its' PBW doubled to 0.06 mT (decreasing the duration to 3.14 ms), Pulse 3 had its' time bandwidth product doubled to 8 (increasing the duration to 12.53 ms), and Pulse 4 had its' PBC shifted to 0.15 mT (keeping the duration of the pulses fixed at 6.27 ms). ω_{off} for the four BSSE pulses were set to 16.370 kHz, 9.485 kHz, 19.250 kHz, and 8.170 kHz, respectively, to match RFSE pulse durations. Magnetization was simulated over a B₁ range of 0-0.5 mT and an off-resonance range of 0-1 kHz.

The results of the off-resonance simulation showed that all RFSE pulses produced a triangular pattern of erroneous excitation where the effective size of the off-resonance field was large compared to the B₁ field. This effect is absent from the BSSE pulse profiles. At the same time, all four BSSE pulses show a small bulk downward shift in the excitation profile with increasing off-resonance, similar to a conventional B₀ gradient-selective excitation pulse. For the four BSSE pulses, the shift was −0.033 mT/kHz, −0.019 mT/kHz, −0.038 mT/kHz, and −0.036 mT/kHz. As expected, the slope of the shift correlated with pulse duration: the pulse with the shortest duration (3.14 ms) also had the smallest bulk shift (−0.019 mT/kHz). A faint N=3 multiphoton resonance was visible with the PBC set to 0.15 mT, at approximately 0.45 mT. The N=3 resonance also exhibited a shift downward in B₁ with off-resonance.

CPMG Sequence Simulation

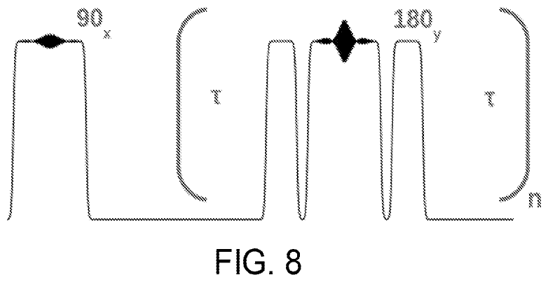

The same excitation pulse was used as the base experiment pulse (PBC=0.14 mT, PBW=0.03 mT, TₑₓB=4, ω_{off}=7.5 kHz, T=6.22 ms), and a BSSE spin echo pulse with the same profile parameters was designed and iteratively refined to eliminate any ramped B₁ distortion. A multi-echo spin echo pulse sequence was constructed using the BSSE excitation and refocusing pulses, and the b_{bs}(t) design algorithm was used to generate a pair of RF pulses serving as B₁ phase rewinder gradients with ω_{off}=7.5 kHz and |K_{BS}| half that of the refocusing pulse (32.2 vs 16.1rad²/G). The 90° BSSE excitation pulse was applied along the x-axis and was followed by eight refocusing pulses applied along the y-axis for an echo train length of 8, with TE=2τ=33 ms. The RF pulse sequence diagram is shown in FIG. 8. The pulses were simulated across a B₁ range of 0 to 0.3 mT and a range of frequency offsets between −200 and 200 Hz, with T₁=T₂=∞.

The results of the multi-echo spin echo sequence simulation showed that the refocusing profile yielded close to full refocusing efficiency within the pulses' 0.03 mT-wide passband. The signal integrated across off-resonance at a location in the passband (0.14 mT) and the stopband (0.17 mT). In the passband evenly spaced echoes were formed, with near-identical signal amplitude produced at each echo. In the stopband, no appreciable signal was produced at the echo times.

### EXAMPLE—EXPERIMENTS

Phantom experiments were performed to verify the magnetization profiles produced by BSSE pulses. A base BSSE pulse with flip angle 90° , PBC=0.14 mT, PBW=0.03 mT, ω_{off}=7.5 kHz, T_{ex B}=4, and total duration T=6.22 ms was designed. Three copies of the pulse were created in which a single parameter was varied: passband center (0.14 mT>0.11 mT) , flip angle (90°>45°), and time-bandwidth product (4>1.5). The pulses were deployed on a 47.5 mT permanent magnet available from Sigwa MRI, of Boston, MA, and image data was acquired using a Tecmag Redstone MRI Console available from Tecmag, Houston, Texas. The system used a 1μs transmit dwell time and amplitude/phase tables for RF waveform definition. A 2kW BT02000-AlphaS Tomco RF power amplifier available from Tomco Rechnologies, Stepney, Australia, was used to drive a 20-turn variable-pitch solenoid RF T/R coil producing a linearly decreasing B₁ gradient. A 50 mL1 mM CuSO4 vial phantom with 30 mm diameter and 115 mm length was imaged using a 3D gradient-recalled echo pulse sequence (TR/TE=27/425 ms, dx/dy/dz=2.0/3.5/3.5 mm, matrix size=128×49×3,5 signal averages), where the BSSE pulses were used for excitation. Conventional B₀ gradients were used for image spatial encoding. B₁ mapping was also performed using the BS shift method as described in Sacolick L I, Wiesinger F, Hancu I, Vogel M W. B1 mapping by Bloch-Siegert shift. Magnetic Resonance in Medicine 2010ᵢ63:1315-1322, with the same 3D gradient-recalled echo sequence but with the addition of a hard pulse excitation. The 6.22 ms, ω_{off}=7.5 kHz component of the BSSE pulse was kept as the B₁-dependent phase shift-generating pulse (K_{BS}=32.2rad²/ G) for B₁ mapping, producing no excitation without the addition of the bex(t) component pulse. To process the images, a mask was created by thresholding a 90° hard pulse GRE acquisition with the same matrix size and resolution to 20% of the maximum signal intensity. This mask was applied to the phase images of the B₁-mapping sequence and magnitudes of the BSSE-excitation images. The B₁ mapping phase image was unwrapped along the coil's gradient dimension, and background phase was subtracted out using a reference scan without a BS shift pulse. B₁ strength was then calculated using the K_{BS}of the off-resonant pulse. The BSSE excitation images were divided by the B₁ map to remove the receive sensitivity of the T/R coil, since |B₁⁺|˜|B₁⁻| at this low frequency.

The measured experimental profiles were produced for the pulses played out in the experiment in the central slice of the 3D acquisition. Corresponding B₁ map were also produced from the same slice. A 1D profile of the experimental case was generated by averaging across the z-dimension of the profile. For the two-flip angle (90° to 45°) experiment, a decrease in signal intensity was observed consistent with the expected 30% decrease based on the nominal flip angles. The ratio of the signals from the 45° and 90° excitations between the passband edges was 0.705 in simulation and 0.627 in the experiment. In the case of decreasing TₑₓB from 4 to 1.5, the TₑₓB=1.5 profile had a wider transition width resulting from the decrease in selectivity. The ratio of the full width at half-maximum of the profiles from the TₑₓB=1.5 excitation and the TₑₓB=4 excitation was 1.29 in simulation and 1.21 in the experiment, showing close agreement. The pulse with PBC shifted to 0.11 mT produced a magnetization profile centered at the intended locations, and the transition bands of the pulses intersected at approximately 0.125 mT, where each profile was expected to reach its half-maximum.

As described above, a class of excitation pulses is provided that can apply the Bloch-Siegert shift for the purpose of selective excitation. Although the Bloch-Siegert shift has been used in MRI for B₁ mapping and in NMR for the calibration of decoupling field power, the present disclosure provides the first systems and methods to use the Bloch-Siegert shift or other far-off-resonant pulse to localize selective excitation. Simulation results showed that the pulses are robust against off-resonance and can be used in pulse sequences requiring phase control, making them a viable choice for a wide range of pulse sequences in B₀-gradient-free imaging systems.

In the non-limiting example provided above, the proposed BSSE pulse design method is based on the Shinnar-Le Roux algorithm, giving BSSE pulses the same advantage in speed of design and ability to predict and trade off design parameters. However, the proposed method also has a number of advantages over RFSE pulses, including the ability to refocus magnetization for spin-echo based pulse sequences and reduced out-of-band excitation in response to B₀ inhomogeneity. RFSE pulses can also be challenging to implement experimentally, because they place strict requirements on the integrated area of the RF envelope, which must be precisely balanced between pulse segments to control large out-of-band excitation. BSSE pulses more tolerant of moderate amplifier errors, which would mainly affect the amplitude of the BS pulse component, leading to more benign slice shifts and widening.

The present disclosure recognizes a variety of practical considerations related to BSSE pulse design. First, there is a tradeoff between pulse duration and pulse ripple, moderated by choice of ω_{off}. Decreasing ω_{off} decreases pulse duration and reduces the required transmitter bandwidth, but may introduce out-of-band excitation if brought too close to resonance. Values of ω_{off}≈7.5 kHz were shown to offer a good compromise between these opposing requirements.

The presence of multiphoton resonances can also be considered. Their positions as a function of B₁ and pulse parameters were derived analytically and confirmed in simulations, which enables them to be taken into consideration in BSSE pulse design, in particular when setting the frequency offset ω_{off} of the b_{bs}(t) pulse. Although their rapid drop off in amplitude with N makes their use for imaging in some situations challenging, the BSSE pulses can be used for multiband multiphoton excitation in some implementations.

The pulse design algorithm described herein can be extended in numerous ways. For example, the VERSE algorithm, such as described in Hargreaves B, Cunningham C, Nishimura D, Conolly S. Variable-rate selective excitation for rapid MRI sequences. Magnetic resonance in medicine 2004; 52:590-597., may be used to allow the frequency-selective excitation pulse to extend onto the time-varying portion of the Bloch-Siegert shift inducing pulse, to shorten overall pulse duration. Additionally, BSSE pulse designs may benefit from joint gradient-based optimization of the two component pulses. Further optimizing the waveforms this way could be used to, for example, reduce multiphoton effects, decrease pulse duration, produce uniform excitation across a broad range of B₁, or constrain the pulses to have a flat amplitude so they can be more easily generated by current-mode amplifiers. Finally, the pulses can be extended to produce Hadamard or other multiband excitations, by designing the excitation pulse bₑₓ(t) using multiband pulse designers developed for B₀ gradient-based selective excitation.

Thus, a new class of pulses has been provided for B 1-selective excitation that localize excitation using frequency gradients produced by the Bloch-Siegert shift. Simulations demonstrate that these pulses produce magnetization profiles of excellent quality with phase control, and that the pulses are robust against off-resonance. Experimental results on an ultra-low-field 47.5 mT verified the design algorithm's ability to control magnetization profile parameters. BSSE pulses be used to enable new methods of B₀-gradient-free acquisition and novel imaging approaches.

The novel pulse described in this disclosure has advantages over previous B₁-selective pulses in that it will allow the user to design pulses to meet target slice profile characteristics. This is an advantageous property for practical use of an RF pulse, and its lack of availability barred the adoption of previous B₁-selective pulses. The novel Bloch-Siegert B₁-selective pulse is simpler and more intuitive in its design and provides a more flexible platform for designing excitations than prior attempts to encode without the use of dedicated gradient coils. The wide latitude in Bloch-Siegert pulses and excitation pulses that can be paired to produce the B₁-selective effect via the systems and methods described in this disclosure allow the pulse to be more readily adapted and improved, and allow the pulse to be applied to novel applications as well as existing applications, such as MR barcoding.

MR barcoding is a technique related to MR fingerprinting which also leverages RF gradient coils. MRF is generally described in U.S. Pat. No. 8,723,518 and Published U.S. Patent Application No. 2015/0301141, each of which is incorporated herein by reference in its entirety for all purposes. In its most basic form, at least two pulses are played out, each of which produces a different flip angle profile across one dimension of that coil. Then a pulse sequence is played out in which one randomly swaps between the at least two pulses and different flip angles and other sequence parameters, so as to produce a very distinct and incoherent signal between at least two voxels (i.e. two regions of interest) that are irradiated by that coil. As a result, one can determine both where the signals are coming from and what some of their NMR properties are. In non-limiting example, one would then have multiple coils that are randomly switched on and off in different combinations, which can help improve the incoherence of the signal over more dimensions. Thus, a pulse sequence and acquisition technique is provided that allows one to both make an image of the NMR properties of the tissue that is being imaged and also determine where the signal is coming from. The pulses described herein can be used for the creation of spatially varying excitation patterns in MR barcoding.

Thus, the Bloch-Siegert B₁-selective pulses may be employed on any MRI imaging system with an inhomogeneous RF coil in order to effect spatial selectivity with the pulses. Furthermore, the Bloch-Siegert B₁-selective pulse is able to achieve more selective excitations than previous pulses with continued optimization. Unlike previous B₁-selective pulses, the Bloch-Siegert B₁-selective pulse can be applied for the same purposes as adiabatic pulses, which produce a uniform excitation across a wide range of B₁ values. Such a pulse is advantageous in a variety of settings, such as when homogeneous excitation is desired from an RF coil with a highly inhomogeneous transmit field, such as a surface coil. The B₁-selective pulse requires less power than commonly used adiabatic pulses such as BIR-4 pulses, providing an advantage in safety. This is a dramatic departure from these previous B₁-selective pulse design techniques.

Thus, Bloch-Siegert B₁⁺-selective pulses can be used as an alternative to B₀ gradients for excitation localization. They can be implemented in traditional MRI systems without the need for any changes in hardware and they can be used in new systems or to enable new systems that do not or will not depend on dedicated gradient coils for encoding. The B₀ gradients used in conventional MR are expensive and bulky and are highly uncomfortable for patients due to their loud acoustic noise and peripheral nerve stimulation. However, they are typically necessary in order to perform slice-selection in conventional MR. The use of Bloch-Siegert B₁⁺ selective pulses are applicable to B₀ gradient-free imaging techniques, such as MR Barcoding or Bloch-Siegert frequency and phase encoding acquisition systems, or systems that combine these encoding techniques with conventional B₀ gradient encoding. With the contribution of excitation localization made by this disclosure, it is possible to create a “fully Bloch-Siegert” or MR Barcoding MR system, utilizing RF gradients instead of x, y, and z B₀ gradients for frequency encoding, phase encoding, and slice-selection. Such a system provides tremendous advantages in cost and patient comfort over current MR systems due to its lack of reliance on B₀ gradients.

In summary, the systems and methods provided herein use a far-off-resonance pulse and an RF pulse that has a spatially-varying RF amplitude so that one obtains a spatial selectivity. Thus, the systems and corresponding methods use an RF coil with a transmit RF field amplitude that varies spatially to play out an off-resonance pulse and a frequency-selective pulse at the same time, either through the same coil or a different coil, for the purpose of spatially localizing an excitation band. If one plays out just the off-resonance pulse, one gets very little excitation. If one plays out just the excitation pulse, one gets no excitation because it is off-resonance from the Larmor frequency (i.e., it's not within the bandwidth of the magnetization). However, if one applies the pulses together, a slice is encoded based on the frequency content of the excitation pulse. Notably, it is be possible to divide the pulses into sub-pulses as individual time segments and play them out in an inter-digitated or interleaved way.

The systems and methods described herein may be used in a variety of additional situations. As just one example, the systems and methods described herein may be used in reduced field of view applications, in which data is acquired from a small region of interest in order to reduce the size of the imaging matrix. A small region of in-plane spins of interest can be excited via the B₁⁺-selective pulse in order to prevent image aliasing. As another non-limiting example, the systems and methods described herein can be used in low-field MRI applications. As described, the systems and methods described herein may be used with MR barcoding, encoding, or other gradient-free RF encoding techniques. For example, one can excite a slice, and then do encoding in a plane or the technique may be applied to different encoding functions. Other RF-based gradient-free methods can be used for slice selection to then encode the signal using different techniques. The systems and methods described herein may also be used with higher field strength applications where one has the ability to control the shape of the RF fields to get sharper transitions between regions of interest for imaging. As a further non-limiting example, the systems and methods provided herein may be used with adiabatic applications, in which the pulse is designed to produce a uniform excitation across a wide range of B₁ amplitudes close to zero, to achieve uniform excitation over a range of B₁ amplitudes produced by an inhomogeneous coil. A range of pulses may be applied with a constant flip angle. An arbitrary flip angle that is not equal to 90 or 180 may be selected to produce a range of inhomogeneous B₁ values.

The method steps described herein are not restricted to being performed in any particular order. Also, structures or systems mentioned in any of the method embodiments may utilize structures or systems mentioned in any of the device/system embodiments. Such structures or systems may be described in detail with respect to the device/system embodiments only but are applicable to any of the method embodiments. Features in any of the embodiments described in this disclosure may be employed in combination with features in other embodiments described herein, such combinations are considered to be within the spirit and scope of the present invention. The contemplated modifications and variations specifically mentioned in this disclosure are considered to be within the spirit and scope of the present invention.

More generally, even though the present disclosure and exemplary embodiments are described above with reference to the examples according to the accompanying drawings, it is to be understood that they are not restricted thereto. Rather, it is apparent to those skilled in the art that the disclosed embodiments can be modified in many ways without departing from the scope of the disclosure herein. Moreover, the terms and descriptions used herein are set forth by way of illustration only and are not meant as limitations. Those skilled in the art will recognize that many variations are possible within the spirit and scope of the disclosure as defined in the following claims, and their equivalents, in which all terms are to be understood in their broadest possible sense unless otherwise indicated.

Thus, the present invention has been described in terms of some preferred embodiments, and it should be appreciated that equivalents, alternatives, variations, and modifications, aside from those expressly stated, are possible and within the scope of the invention.

1. A method for using a nuclear magnetic resonance (NMR) system, the method including steps comprising:
applying an off-resonance radio frequency (RF) pulse using a radio-frequency coil that is spatially inhomogeneous to induce a B₁-dependent resonant frequency shift in spins in a subject;
in the presence of the off-resonance RF pulse, applying a frequency-modulated, frequency-selective RF excitation pulse to spatially encode the spins in the subject;
acquiring NMR data from the subject that is spatially encoded; and
reconstructing the NMR data to produce a report of internal materials forming the subject.

2. The method of claim 1, wherein the report includes at least one of an image of the subject, a map of the subject, or a quantitative measure of function or the internal materials of the subject.

3. The method of claim 1, wherein the off-resonance RF pulse produces a Bloch-Siegert shift.

4. The method of claim 1, wherein the off-resonance RF pulse and the frequency-modulated, frequency-selective RF excitation pulse are both applied using the RF coil.

5. The method of claim 1, wherein the off-resonance RF pulse and the frequency-modulated, frequency-selective RF excitation pulse are applied simultaneously.

6. The method of claim 1, further comprising interleaving the off-resonance RF pulse and the frequency-modulated, frequency-selective RF excitation pulse.

7. The method of claim 1, wherein the frequency-modulated, frequency-selective RF excitation pulse a frequency modulation waveform that is transformed into an amplitude modulation waveform using a variable-rate selective excitation (VERSE) to control distortions due to limited amplifier bandwidth.

8. The method of claim 1, wherein the off-resonance RF pulse and the frequency-modulated, frequency-selective RF excitation pulse are superimposed to produce a selective B₁ excitation in the subject that is dependent on a frequency modulation of both the off-resonance RF pulse and the frequency-modulated, frequency-selective RF excitation pulse.

9. A magnetic resonance imaging (MRI) system comprising:
a magnet system configured to generate a polarizing magnetic field about a portion of the subject positioned in the MRI system;
a radio frequency (RF) system configured to deliver RF pulses to the subject, and acquire therefrom magnetic resonance image (MRI) data;
at least one processor configured to:
control the RF system to apply an off-resonance RF pulse using an RF coil of the RF system that is spatially inhomogeneous to induce a B₁-dependent resonant frequency shift in spins in the subject;
control the RF system to apply, in the presence of the off-resonance RF pulse, a frequency-modulated, frequency-selective RF excitation pulse to spatially encode the spins in the subject;
control the RF system to acquire the MRI data from the subject that is spatially encoded; and
reconstruct the MRI data to produce a report of internal materials forming the subject.

10. The system of claim 9, wherein the report includes at least one of an image of the subject, a map of the subject, or a quantitative measure of function or the internal materials of the subject.

11. The system of claim 9, wherein the off-resonance RF pulse produces a Bloch-Siegert shift.

12. The system of claim 9, wherein the off-resonance RF pulse and the frequency-modulated, frequency-selective RF excitation pulse are both applied using the RF coil.

13. The system of claim 9, wherein the at least one processor is further programmed to simultaneously apply the off-resonance RF pulse and the frequency-modulated, frequency-selective RF excitation pulse.

14. The system of claim 9, wherein the at least one processor is further configured to interleave the off-resonance RF pulse and the frequency-modulated, frequency-selective RF excitation pulse.

15. A method for generating images or maps of a subject using a nuclear magnetic resonance (NMR) system, the method including steps comprising:
applying an off-resonance radio frequency (RF) pulse using a radio-frequency coil that is spatially inhomogeneous to induce a B₁-dependent resonant frequency shift in spins in a subject;
in the presence of the off-resonance RF pulse, applying a frequency-selective RF excitation pulse that is frequency modulated to correspond to a B₁ of interest to spatially encode the spins in the subject;
acquiring NMR data from the subject that is spatially encoded; and
reconstructing the NMR data to produce the images or maps of the subject.

16. The method of claim 15, wherein the off-resonance RF pulse and the frequency-modulated, frequency-selective RF excitation pulse are both applied using the RF coil.

17. The method of claim 15, wherein the off-resonance RF pulse and the frequency-modulated, frequency-selective RF excitation pulse are applied simultaneously.

18. The method of claim 15, further comprising interleaving the off-resonance RF pulse and the frequency-modulated, frequency-selective RF excitation pulse.

19. The method of claim 15, wherein the off-resonance RF pulse and the frequency-modulated, frequency-selective RF excitation pulse are superimposed to produce a selective B₁ excitation in the subject that is dependent on a frequency modulation of both the off-resonance RF pulse and the frequency-modulated, frequency-selective RF excitation pulse.

20. The method of claim 15, wherein the off-resonance RF pulse includes a flip angle other than 90 or 180 degrees to produce a range of in homogenous values of a B₁ field within a selection region of the subject.

21. The method of claim 20, wherein a variation of the flip angle is less than a variation of the B₁-dependent resonant frequency shift in the region.
